(19) United States
(12) Patent Application Publication
(10) Pub. No.: US 2014/0117293 A1
(43) Pub. Date: May 1, 2014

(54) COATING SOLUTION FOR FORMING LIGHT-ABSORBING LAYER, AND METHOD OF PRODUCING COATING SOLUTION FOR FORMING LIGHT-ABSORBING LAYER

(71) Applicant: TOKYO OHKA KOGYO CO., LTD., Kawaski-shi (JP)

(72) Inventors: Masaru Kuwahara, Hillsboro, OR (US); Koichi Misumi, Hillsboro, OR (US); Hidenori Miyamoto, Hillsboro, OR (US)

(73) Assignee: TOKYO OHKA KOGYO CO., LTD., Kawasaki-shi (JP)

(21) Appl. No.: 13/662,870

(22) Filed: Oct. 29, 2012

(51) Int. Cl. H01L 31/0216

(52) U.S. Cl. CPC H01L 31/0216
USPC 252/582

(57) ABSTRACT

A coating solution for forming a light-absorbing layer of a solar cell obtainable by dissolving at least one metal or metal compound selected from the group consisting of a group 11 metal, a group 12 metal, a group 13 metal, a group 14 metal, a group 11 metal compound, a group 12 metal compound, a group 13 metal compound and a group 14 metal compound in a solvent to obtain a metal complex solution, and adding 0.1 to 50 volume % of an alcohol having 1 to 5 carbon atoms to the metal complex solution.

### TECHNICAL FIELD

The present invention relates to a coating solution for forming a light-absorbing layer, and a method of producing the coating solution.

### DESCRIPTION OF RELATED ART

In recent years, in consideration of environment, solar cells have been attracting a growing interest. In particular, attention has been drawn to chalcopyrite solar cells which are thin-film solar cells with high photoelectric conversion efficiency, and also CZTS solar cells which have a rare metal such as indium used in a chalcopyrite solar cell substituted with another element, and hence, research and development have been actively conducted.

A chalcopyrite solar cell is produced by forming a light absorbing layer prepared from a chalcopyrite material on a substrate. Representative elements of a chalcopyrite material include copper (Cu), indium (In), gallium (Ga), selenium (Se) and sulfur (S), and representative examples of a light absorbing layer include Cu(In, Ga)Se₂ and Cu(In, Ga)(Se, S)₂, which are abbreviated as CIGS and CIGSSe, respectively. Recently, CZTS solar cell has been studied in which a rare metal indium has been substituted and is composed of, for example, copper (Cu), zinc (Zn), tin (Sn), selenium (Se) and sulfur (S). Representative examples of the light absorbing layer of such a solar cell include Cu₂ZnSnSe₄, Cu₂ZnSnS₄ and Cu₂ZnSn(S, Se)₄.

FIG. 1 is a schematic cross-sectional diagram of an example of a chalcopyrite solar cell or a CZTS solar cell.

As shown in FIG. 1, a chalcopyrite solar cell or a CZTS solar cell 1 has a basic structure in which a first electrode 3 (back electrode), a CIGS or CZTS layer 4, a buffer layer 5, an i-ZnO layer 6 and a second electrode 7 are laminated on a substrate 2 in this order. As the buffer layer, for example, a CdS layer, an ZnS layer and an InS layer are known.

Each of the first electrode 3 and the second electrode 7 has a terminal connected thereto, and each of the terminals is connected to a wiring. In such a chalcopyrite solar cell or a CZTS solar cell 1, an incident light entering in the direction of A is absorbed by the CIGS or CZTS layer 4 to generate an electromotive force, and an electric current flows in the direction of B.

The surface of the second electrode 7 is, for example, covered with an anti-reflection film layer 8 composed of an MgF₂ layer for protection.

As a method of forming a CIGS or CZTS layer 4, a sputtering method and a coating method are known. However, in the sputtering method, the size of the apparatus tends to be scaled up, thereby deteriorating the yield. Therefore, diligent studies have been made on the coating method which enables production at a relatively low cost.

Generally, in a coating method of a CIGS layer, elements such as Cu, In, Ga, Se and S are dissolved in a specific solvent to prepare a coating solution, and the coating solution is applied to a substrate by a spin coating method or a dipping method, followed by baking, thereby forming a CIGS layer (see for example, Patent Document 1 and Patent Document 2).

In the preparation of a coating solution, there are known a method in which hydrazine is used as the solvent, and a method in which amine is added as a dissolution promoter instead of using hydrazine. Further, in a coating method of a CZTS layer, elements such as Cu, Zn, Sn, Se and S are dissolved in a specific solvent to prepare a coating solution, and the coating solution is applied to a substrate by a spin coating method or a dipping method, followed by baking, thereby forming a CZTS layer. (see Patent Document 3)

### DOCUMENTS OF RELATED ART

### Patent Document

[Patent Document 1] U.S. Pat. No. 7,094,651
[Patent Document 2] U.S. Pat. No. 7,517,718
[Patent Document 3] U.S. Pre-grant Patent Publication No. 2011/0094557

### SUMMARY OF THE INVENTION

However, the above metal complex coating solution posed a problem in terms of affinity for the first electrode (back electrode), in particular, affinity for Mo. Therefore, there were high risks of agglomeration of the coating solution soon after applying the coating solution to a substrate, and generation of cracks in the coating film during the following baking step.

In view of these problems, there have been demands for a coating solution for forming a light-absorbing layer of a solar cell by using metals as raw materials, and a method of producing the same. However, such an effective, suitable method has not been proposed under these circumstances.

For solving the above-mentioned problems, the present invention employs the following embodiments.

Specifically, a first aspect of the present invention is a coating solution for forming a light-absorbing layer of a solar cell (hereafter, sometimes referred to simply as “a coating solution for forming a light-absorbing layer”) obtainable by dissolving at least one metal or metal compound selected from the group consisting of a group 11 metal, a group 12 metal, a group 13 metal, a group 14 metal, a group 11 metal compound, a group 12 metal compound, a group 13 metal compound and a group 14 metal compound in a solvent to obtain a metal complex solution, and adding 0.1 to 50 volume % of an alcohol having 1 to 5 carbon atoms to the metal complex solution.

Further, a second aspect of the present invention is a method of forming a coating solution for forming a light-absorbing layer of a solar cell, the method including: a step of dissolving at least one metal or metal compound selected from the group consisting of a group 11 metal, a group 12 metal, a group 13 metal, a group 14 metal, a group 11 metal compound, a group 12 metal compound, a group 13 metal compound and a group 14 metal compound in a solvent to obtain a metal complex solution; and a step of adding 0.1 to 50 volume % of an alcohol having 1 to 5 carbon atoms to the metal complex solution.

According to the present invention, there are provided a coating solution for forming a light-absorbing layer of a solar cell, and a method of producing the same, which improve the affinity for the back electrode, remedy agglomeration of the coating solution which occurs after coating and before baking, and enables production of a uniform light-absorbing layer.

### BRIEF DESCRIPTION OF THE DRAWINGS

FIG. 1 is a schematic cross-sectional diagram of an example of a chalcopyrite solar cell or a CZTS solar cell.

FIG. 2 is a photograph of the CZTS layer formed using the coating solution produced in Example 1, as measured by a scanning electron microscope (SEM).

FIG. 3 is a photograph of the CZTS layer formed using the coating solution produced in Comparative Example 1, as measured by a scanning electron microscope (SEM).

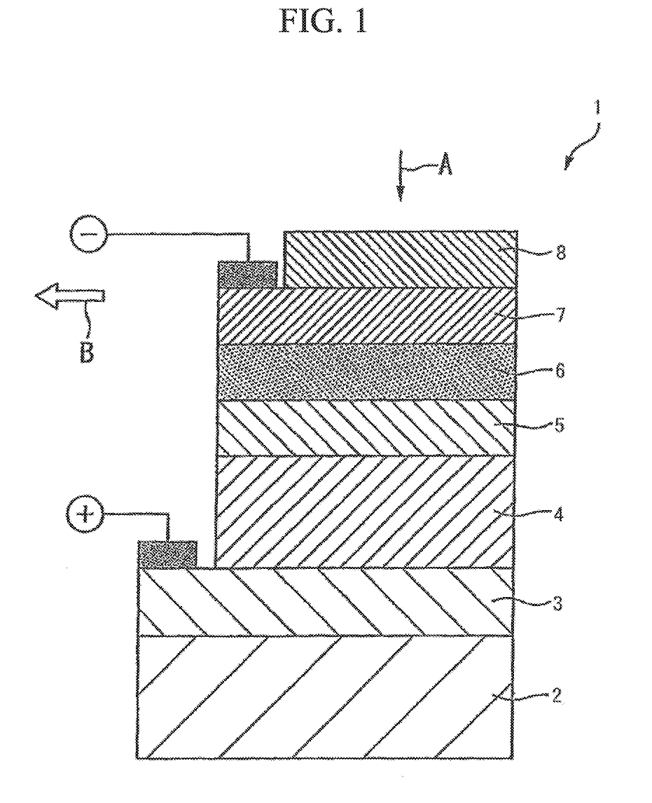

### DETAILED DESCRIPTION OF THE INVENTION

### Coating Solution for Forming a Light-Absorbing Layer and Method of Producing the Same

Hereinbelow, the coating solution for forming a light-absorbing layer according to the present invention and a method of producing the same will be described.

The coating solution for forming a light-absorbing layer according to the present invention is obtainable by dissolving at least one metal or metal compound selected from the group consisting of a group 11 metal, a group 12 metal, a group 13 metal, a group 14 metal, a group 11 metal compound, a group 12 metal compound, a group 13 metal compound and a group 14 metal compound in a solvent to obtain a metal complex solution, and adding 0.1 to 50 volume % of an alcohol having 1 to 5 carbon atoms to the metal complex solution.

In the present invention, the at least one metal or metal compound selected from the group consisting of a group 11 metal, a group 12 metal, a group 13 metal, a group 14 metal, a group 11 metal compound, a group 12 metal compound, a group 13 metal compound and a group 14 metal compound (hereafter, sometimes referred to simply as “metal and/or metal compound”) is not particularly limited, as long as it is used for a light-absorbing layer of a solar cell.

Examples of the group 11 metal include Cu element and Ag element. Among these examples, Cu element is particularly desirable.

Examples of the group 12 metal include Zn element and Cd element. Among these examples, Zn element is particularly desirable.

Examples of the group 13 metal include Al element, Ga element and In element. Among these examples, Ga element and In element are particularly desirable.

Examples of the group 14 metal include Si element, Ge element and Sn element. Among these examples, Ge element and Sn element are particularly desirable.

Examples of the group 11 metal compound include Cu metal (Cu powder), Cu(OH)₂, Cu₂S, Cu₂Se, CuO, Cu₂O, silver oxide and silver sulfide.

Examples of the group 12 metal compound include Zn metal (Zn powder), ZnS, ZnSe, ZnO and zinc hydroxide.

Examples of the group 13 metal compound include In metal (In powder), Ga metal (Ga Powder), In₂S₃, In₂Se₃, indium oxide, indium sulfide and gallium oxide.

Examples of the group 14 metal compound include Sn metal (Sn powder), SnSe, SnSe₂, SnS, SnO and germanium oxide.

In the present invention, as the metal and/or metal compound, at least one member selected from the group consisting of Cu element, Zn element, Ga element, In element, Ge element, Sn element, Cu metal, Cu(OH)₂, Cu₂S, Cu₂Se, CuO, Cu₂O, silver oxide, silver sulfide, Zn metal, ZnSe, ZnO, zinc hydroxide, In₂Se₃, indium oxide, indium sulfide, gallium oxide, Sn metal, SnS, SnSe, SnSe₂, SnO and germanium oxide is preferable.

For example, when the coating solution for forming a light-absorbing layer is used for CZTS solar cell, the metal and/or metal compound is preferably a combination of at least one member selected from the group consisting of Cu element, Cu metal, Cu(OH)₂, CuS, Cu₂S, CuSe, Cu₂Se, CuO and Cu₂O as a Cu component, at least one member selected from the group consisting of Zn element, Zn metal, ZnSe, ZnO and zinc hydroxide as a Zn component, and at least one member selected from the group consisting of Sn element, Sn metal, SnS, SnSe, SnSe₂ and SnO as an Sn component, more preferably a combination of at least one member selected from the group consisting of Cu metal and Cu₂Se, at least one member selected from the group consisting of Zn metal and ZnSe, and at least one member selected from the group consisting of Sn metal, SnSe and SnSe₂, and still more preferably a combination of Cu metal, ZnSe and Sn metal.

Alternatively, for example, when the coating solution for forming a light-absorbing layer is used for CIGS solar cell, the metal and/or metal compound is preferably a combination of at least one member selected from the group consisting of Cu metal, Cu(OH)₂, CuS, Cu₂S, CuSe, Cu₂Se, CuO and Cu₂O as a Cu component, at least one member selected from the group consisting of In element, In₂Se₃, In₂S₃ and indium oxide as an In component, and at least one member selected from the group consisting of Ga metal, GaS, Ga₂S, GaSe and Ga₂Se₃ as a Ga component, more preferably a combination of at least one member selected from the group consisting of Cu metal and Cu₂Se, at least one member selected from the group consisting of In, In₂S₃ and In₂Se₃, and at least one member selected from the group consisting of Ga element and Ga metal, and still more preferably a combination of Cu metal, In₂Se₃ and Ga metal.

In the present invention, the solvent is not particularly limited, as long as it is capable of dissolving the metal and/or metal compound.

Examples of the solvent include polar aprotic solvents, such as dimethyl sulfoxide (DMSO), N-methylpyrrolidone (NMP), N-methylformamide (NMF) and dimethylformamide (DMF); hydrazine; water; and alcohols and glycolethers exhibiting a high water solubility, such as ethanol and methyldiglycol (MDG). As the solvent, one type of solvent may be used alone, or two or more types of solvents may be used in combination.

Among these, dimethyl sulfoxide, water, and a combination of dimethyl sulfoxide and water are preferable. From the viewpoint of solubility of metal, dimethyl sulfoxide is particularly preferable.

The amount of the solvent can be appropriately adjusted so as to satisfactorily dissolve the metal and/or metal compound, depending on the type of the metal and/or metal compound. However, the amount of the solvent is preferably in a range where the solid content of the metal complex solution is from 0.1 to 20% by weight, more preferably from 1 to 15% by weight, and still more preferably 3 to 12% by weight.

In the present invention, after dissolving the metal and/or metal compound in a solvent to obtain a metal complex solution, 0.1 to 50 volume % of an alcohol having 1 to 5 carbon atoms is added to the metal complex solution.

Examples of the alcohol of 1 to 5 carbon atoms include methanol, ethanol, isopropanol (IPA), n-butyl alcohol, sec-butyl alcohol, isobutyl alcohol, tert-butyl alcohol, 1-pentanol, 2-pentanol, 3-pentanol, 2-methyl-1-butanol, 3-methyl-1-butanol, 2-methyl-2-butanol, 3-methyl-2-butanol, 2,2-dimethyl-1-propanol, ethylene glycol and glycerin. Among these, methanol, ethanol and isopropanol (IPA) are preferable, and ethanol is most preferable.

In the present invention, it is necessary to add 0.1 to 50 volume % of an alcohol having 1 to 5 carbon atoms, based on the metal complex solution.

The amount of the alcohol having 1 to 5 carbon atoms added is preferably 0.1 to 40 volume %, and more preferably 0.1 to 30 volume %.

When the amount of the alcohol having 1 to 5 carbon atoms added is at least as large as the lower limit of the above-mentioned range, the effect of adding the alcohol having 1 to 5 carbon atoms can be obtained. On the other hand, when the amount of the alcohol having 1 to 5 carbon atoms added is no more than the upper limit of the above-mentioned range, the homogeneity of the metal complex solution can be maintained without occurrence of precipitation in the coating solution.

In the present invention, as the metal complex solution, there is no particular limitation as long as it is suitable for forming a light absorbing layer of a solar cell. However, the metal complex solution is preferably a CZTS complex solution or a CIGS complex solution.

Hereinbelow, a CZTS complex solution and a CIGS complex solution according to the present embodiment will be described.

[CZTS Complex Solution]

The CZTS complex solution according to the present embodiment is obtainable by dissolving a hydrazine-coordinated Cu chalcogenide complex component, a hydrazine-coordinated Sn chalcogenide complex component and a hydrazine-coordinated Zn chalcogenide complex component in dimethylsulfoxide (DMSO).

(Hydrazine-Coordinated Cu Chalcogenide Complex Component)

In the present embodiment, the hydrazine-coordinated Cu chalcogenide complex component is obtainable by reacting Cu or Cu₂Se with a chalcogen in dimethyl sulfoxide in the presence of hydrazine, followed by concentration and filtration.

More specifically, for example, a Cu metal and 2 to 4 equivalents of Se are reacted in dimethylsulfoxide (DMSO) in the presence of hydrazine, and stirred at room temperature for about 3 to 7 days. Thereafter, the remaining hydrazine is preferably removed under reduced pressure, followed by concentration, and subjecting the obtained concentrated solution to filtration, thereby obtaining a hydrazine-coordinated Cu chalcogenide complex/DMSO solution.

Alternatively, the hydrazine-coordinated Cu chalcogenide complex component can be obtained by dissolving a Cu metal and a chalcogen in DMSO having hydrazine added thereto, and adding a poor solvent to the resulting solution, followed by recrystallization.

More specifically, a Cu metal and a chalcogen are reacted in DMSO in the presence of hydrazine, and stirred at room temperature for about 3 to 7 days. Then, hydrazine is removed from the resulting solution while flowing nitrogen, followed by filtration. Thereafter, a poor solvent is added to the filtrate to perform a recrystallization, thereby obtaining a black hydrazine-coordinated Cu chalcogenide complex.

As the chalcogen, Se or S can be used, and Se is preferable. As Cu, not only a Cu metal, but also copper selenide (Cu₂Se) may be used.

As hydrazine, anhydrous hydrazine may be used, although hydrazine monohydrate or hydrazine containing water (hereafter, referred to as “water-containing hydrazine”) is preferable. Anhydrous hydrazine vigorously reacts with selenium, whereas hydrazine monohydrate or a water-containing hydrazine mildly reacts with selenium. Therefore, hydrazine monohydrate or a water-containing hydrazine is preferable in terms of ease in handling in the synthesis process. The water content of the water-containing hydrazine is preferably 63% by weight or more.

As the poor solvent, at least one member selected from the group consisting of alcohols of 1 to 5 carbon atoms is preferable. Examples of the alcohols of 1 to 5 carbon atoms include methanol, ethanol, isopropanol (IPA), n-butyl alcohol, sec-butyl alcohol, isobutyl alcohol, tert-butyl alcohol, 1-pentanol, 2-pentanol, 3-pentanol, 2-methyl-1-butanol, 3-methyl-1-butanol, 2-methyl-2-butanol, 3-methyl-2-butanol, 2,2-dimethyl-1-propanol, ethylene glycol and glycerin. Among these, methanol, ethanol and isopropanol (IPA) are preferable, and isopropanol (IPA) is most preferable.

With respect to the amount of Cu and the chalcogen, it is preferable to use 2 to 4 mol of the chalcogen, per 1 mol of Cu. Further, it is preferable to dissolve Cu and the chalcogen in DMSO having about 2 mol of hydrazine added thereto.

The generation of the hydrazine-coordinated Cu chalcogenide complex described above can be expressed by a chemical formula (1) shown below.

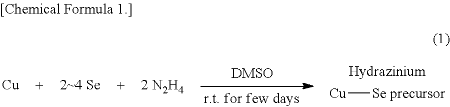

(Hydrazine-Coordinated Sn Chalcogenide Complex Component)

The hydrazine-coordinated Sn chalcogenide complex component used in the present embodiment is required to be generated so as to be soluble in DMSO. The hydrazine-coordinated Sn chalcogenide complex can be generated, for example, by adding Sn metal and a chalcogen in hydrazine to obtain a crude product, extracting the crude product with DMSO, adding a poor solvent to the resulting solution, followed by reprecipitation.

More specifically, Sn metal and a chalcogen are added to hydrazine, and stirred at room temperature for about 1 to 3 days. Then, hydrazine is removed from the resulting solution while flowing nitrogen to obtain a crude product. Thereafter, the obtained crude product is extracted with DMSO.

Subsequently, the extraction solution obtained by extracting the crude product is subjected to filtration using, for example, a 0.2 μm PTFE filter, followed by concentration. Then, a poor solvent is added to the concentration solution to perform a reprecipitation, and the supernatant is removed. The precipitate is washed with IPA and dried, thereby obtaining a dark-yellow hydrazine-coordinated Sn chalcogenide complex.

Alternatively, the hydrazine-coordinated Sn chalcogenide complex can be prepared as follows. A metal Sn and 3 equivalents of Se are stirred in hydrazine (5 ml) at room temperature for 1 to 3 days. Then, IPA is added and stirred, and a yellow product is precipitated. The supernatant is removed, and the precipitate is washed with IPA and dried, thereby obtaining a crude product.

Subsequently, the crude product is subjected to extraction with DMSO (80° C., 1 hr), followed by concentration. The resulting concentrated solution is subjected to filtration, thereby obtaining a hydrazine-coordinated Sn—Se chalcogenide complex/DMSO solution.

The generation of the hydrazine-coordinated Sn chalcogenide complex component described above can be expressed by a chemical formula (2) shown below.

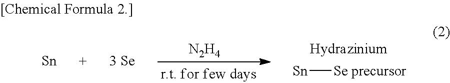

As the chalcogen, Se or S can be used, and Se is preferable. As Sn, not only a Sn metal, but also Sn selenide (SnSe, SnSe₂) may be used. Further, as the poor solvent, the same poor solvents as those described above for the hydrazine-coordinated Cu chalcogenide complex component can be mentioned, and methanol, ethanol and isopropanol (IPA) are preferable. As hydrazine, anhydrous hydrazine may be used, although hydrazine monohydrate or a water-containing hydrazine is preferable. With respect to the amount of Sn and the chalcogen, it is preferable to use 3 mol of the chalcogen, per 1 mol of Sn.

(Hydrazine-Coordinated Zn Chalcogenide Complex Component)

The hydrazine-coordinated Zn chalcogenide complex component used in the present embodiment is required to be generated so as to be soluble in DMSO. The hydrazine-coordinated Zn chalcogenide complex component can be generated, for example, by mixing Zn or ZnSe and a chalcogen in the presence of hydrazine to obtain a crude product, followed by extracting the crude product with dimethylsulfoxide.

More specifically, Zn selenide and a chalcogen are added to hydrazine in DMSO, and stirred at room temperature for about 3 to 7 days. Then, hydrazine is removed from the resulting solution while flowing nitrogen to obtain a crude product (reaction intermediate solution). Thereafter, the obtained crude product is extracted with DMSO.

Subsequently, the extraction solution obtained by extracting the crude product is subjected to filtration using, for example, a 0.2 μm PTFE filter, followed by concentration. The resulting concentrated solution is subjected to filtration, thereby obtaining a hydrazine-coordinated Zn chalcogenide complex component.

The generation of the hydrazine-coordinated Zn chalcogenide complex component described above can be expressed by a chemical formula (3) shown below.

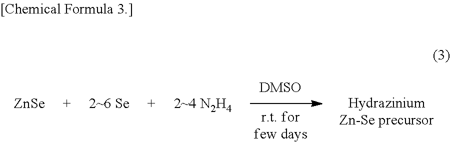

As the chalcogen, Se or S can be used, and Se is preferable. As Zn, not only Zn selenide, but also Zn metal may be used. As hydrazine, anhydrous hydrazine may be used, although hydrazine monohydrate or a water-containing hydrazine is preferable. Further, as the reaction solvent, hydrazine may be used instead of DMSO. With respect to the amount of Zn selenide (ZnSe) and the chalcogen, it is preferable to use 2 mol or more of the chalcogen, per 1 mol of Zn selenide, and it is more preferable to use 3 to 4 mol of the chalcogen, per 1 mol of Zn selenide.

[Method of Producing CZTS Complex Solution]

Next, a method of producing a CZTS complex solution will be described.

Firstly, DMSO is added to the aforementioned hydrazine-coordinated Cu chalcogenide complex component and stirred at room temperature for about one night, thereby obtaining a DMSO solution having the hydrazine-coordinated Cu chalcogenide complex component dissolved therein (first solution).

Further, DMSO is added to the aforementioned hydrazine-coordinated Sn chalcogenide complex component and stirred at a temperature of 80 to 120° C. for about 1 hour, thereby obtaining a DMSO solution having the hydrazine-coordinated Sn chalcogenide complex component dissolved therein (second solution).

Further, DMSO is added to the aforementioned hydrazine-coordinated Zn chalcogenide complex component and stirred at a temperature of 80 to 120° C. for about 1 hour, thereby obtaining a DMSO solution having the hydrazine-coordinated Zn chalcogenide complex component dissolved therein (third solution).

Subsequently, the DMSO solution having the hydrazine-coordinated Cu chalcogenide complex component dissolved therein, the DMSO solution having the hydrazine-coordinated Sn chalcogenide complex component dissolved therein and the DMSO solution having the hydrazine-coordinated Zn chalcogenide complex component dissolved therein are mixed together.

In the manner as described above, a CZTS complex solution according to the present embodiment can be produced.

In the CZTS complex solution according to the present embodiment, for improving the film quality (grain size and crystal quality) of the light absorbing layer, an Na additive solution may be added.

The Na additive solution can be obtained, for example, as follows. 2 equivalents of Se is added to sodium selenide (Na₂Se), followed by stirring in DMSO at room temperature for 3 to 1 week, thereby obtaining a homogeneous black solution.

The CZTS complex solution according to the present embodiment uses DMSO as the solvent, and the coating solution itself does not contain hydrazine. As a result, the chemical properties (explosiveness) of hydrazine in the formation of a light-absorbing layer would not be of any problems, thereby improving the safety of the production process.

Further, since hydrazine-coordinated metal chalcogenide complexes are uniformly dissolved in the solution, storage stability is increased, and the freedom of the choice of the coating apparatus is improved.

In the CZTS complex solution according to the present embodiment, if desired, a miscible additive may be included as long as the effects of the present invention are not impaired, for example, an organic solvent for adjusting the viscosity, an additive resin for improving the performance of the film, a surfactant for improving the applicability or a stabilizer.

[CIGS Complex Solution]

### First Embodiment

Hereafter, the CIGS complex solution according to a first mode of the present embodiment will be described.

The CIGS complex solution according to the present embodiment is obtainable by dissolving a hydrazine-coordinated Cu chalcogenide complex component, a hydrazine-coordinated In chalcogenide complex component and a hydrazine-coordinated Ga chalcogenide complex component in dimethylsulfoxide (DMSO).

(Hydrazine-Coordinated Cu Chalcogenide Complex Component)

As the hydrazine-coordinated Cu chalcogenide complex component, the hydrazine-coordinated Cu chalcogenide complex for the aforementioned CZTS complex solution can be used.

(Hydrazine-Coordinated in Chalcogenide Complex Component)

The hydrazine-coordinated In chalcogenide complex component used in this embodiment is required to be generated so as to be soluble in DMSO. The hydrazine-coordinated In chalcogenide complex component can be generated, for example, by adding In selenide (In₂Se₃) and a chalcogen in hydrazine to obtain a crude product (a first crude product), extracting the crude product with DMSO, adding a poor solvent to the resulting solution, followed by reprecipitation.

More specifically, In selenide and a chalcogen are added to hydrazine, and stirred at room temperature for about 3 to 7 days. Then, hydrazine is removed from the resulting solution while flowing nitrogen to obtain a crude product. Thereafter, the obtained crude product is extracted with DMSO.

Subsequently, the extraction solution obtained by extracting the crude product is subjected to filtration using, for example, a 0.2 μm PTFE filter, followed by concentration. Then, a poor solvent is added to the concentration solution to perform a reprecipitation, and the supernatant is removed. The precipitate is washed with IPA and dried, thereby obtaining a dark-red hydrazine-coordinated In chalcogenide complex component.

The generation of the hydrazine-coordinated In chalcogenide complex component described above can be expressed by a chemical formula (4) shown below.

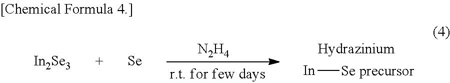

As the chalcogen, Se or S can be used, and Se is preferable. As In, not only In selenide, but also In metal may be used. Further, as the poor solvent, the same poor solvents as those described above for the hydrazine-coordinated Cu chalcogenide complex component can be mentioned, and methanol, ethanol and isopropanol (IPA) are preferable. As hydrazine, anhydrous hydrazine may be used, although hydrazine monohydrate is preferable. With respect to the amount of In selenide (In₂Se₃) and the chalcogen, it is preferable to use 1 mol or more of the chalcogen, per 1 mol of In selenide.

As described above, in the present embodiment, the hydrazine-coordinated In chalcogenide complex component is obtained by extracting with a DMSO solution, followed by reprecipitation. As a result, the thus obtained hydrazine-coordinated In chalcogenide complex component exhibits improved solubility in a DMSO solution.

(Hydrazine-Coordinated Ga Chalcogenide Complex Component)

The hydrazine-coordinated Ga chalcogenide complex component used in this embodiment is required to be generated so as to be soluble in DMSO. The hydrazine-coordinated Ga chalcogenide complex component can be generated, for example, by adding Ga metal and a chalcogen in hydrazine to obtain a crude product (a second crude product), extracting the crude product with DMSO, adding a poor solvent to the resulting solution, followed by reprecipitation.

More specifically, Ga metal and a chalcogen are added to hydrazine, and stirred at room temperature for about 7 days. Then, hydrazine is removed from the resulting solution while flowing nitrogen to obtain a crude product. Thereafter, the obtained crude product is extracted with DMSO.

Subsequently, the extraction solution obtained by extracting the crude product is subjected to filtration using, for example, a 0.2 μm PTFE filter, followed by concentration. Then, a poor solvent is added to the concentration solution to perform a reprecipitation, and the supernatant is removed. The precipitate is washed with IPA and dried, thereby obtaining a dark-brown hydrazine-coordinated Ga chalcogenide complex component.

The generation of the hydrazine-coordinated Ga chalcogenide complex component described above can be expressed by a chemical formula (5) shown below.

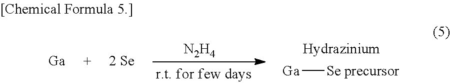

As the chalcogen, Se or S can be used, and Se is preferable. Further, as the poor solvent, the same poor solvents as those described above for the hydrazine-coordinated Cu chalcogenide complex component can be mentioned, and methanol, ethanol and isopropanol (IPA) are preferable. As hydrazine, anhydrous hydrazine may be used, although hydrazine monohydrate or a water-containing hydrazine is preferable. With respect to the amount of Ga and the chalcogen, it is preferable to use 2 mol or more of the chalcogen, per 1 mol of Ga.

As described above, in the present embodiment, the hydrazine-coordinated Ga chalcogenide complex component is obtained by extracting with a DMSO solution, followed by reprecipitation. As a result, the thus obtained hydrazine-coordinated Ga chalcogenide complex component exhibits improved solubility in a DMSO solution.

Next, a method of producing a CIGS complex solution will be described.

Firstly, DMSO is added to the aforementioned hydrazine-coordinated Cu chalcogenide complex component and stirred at room temperature for about one night, thereby obtaining a DMSO solution having the hydrazine-coordinated Cu chalcogenide complex component dissolved therein (solution (I)).

Further, DMSO is added to the aforementioned hydrazine-coordinated In chalcogenide complex component and stirred at a temperature of 80 to 120° C. for about 1 hour, thereby obtaining a DMSO solution having the hydrazine-coordinated In chalcogenide complex component dissolved therein (solution (II)).

Furthermore, DMSO is added to the aforementioned hydrazine-coordinated Ga chalcogenide complex component and stirred at a temperature of 80 to 120° C. for about 1 hour, thereby obtaining a DMSO solution having the hydrazine-coordinated Ga chalcogenide complex component dissolved therein (solution (III)).

Subsequently, the DMSO solution having the hydrazine-coordinated Cu chalcogenide complex component dissolved therein, the DMSO solution having the hydrazine-coordinated In chalcogenide complex component dissolved therein and the DMSO solution having the hydrazine-coordinated Ga chalcogenide complex component dissolved therein are mixed together.

In the manner as described above, a CIGS complex solution according to the present embodiment can be produced.

In the CIGS complex solution according to the present embodiment, DMSO is used as the solvent. As a result, the storage stability is improved as compared to a conventional coating solution.

Specifically, when hydrazine is used by a conventional method, a problem arises in that Cu₂Se is precipitated. For example, when hydrazine is used as a solvent, and a solution (I) prepared from Cu₂S and S and a solution (II) prepared from In₂Se₃, Ga and Se are mixed together, Cu₂S in the first solution reacts with Se in the second solution to cause the precipitation. The precipitation of Cu₂S was observed after about 2 weeks.

In contrast, the coating solution for forming a light-absorbing layer according to the present embodiment was not deteriorated even after 1 month, meaning that the coating solution exhibited excellent storage stability.

Further, since the coating solution itself does not contain hydrazine, the chemical properties (explosiveness) of hydrazine in the formation of a light-absorbing layer would not be of any problems, thereby improving the safety of the production process.

In the CIGS complex solution according to the present embodiment, if desired, a miscible additive may be included as long as the effects of the present invention are not impaired, for example, an organic solvent for adjusting the viscosity, an additive resin for improving the performance of the film, a surfactant for improving the applicability or a stabilizer.

### Second Embodiment

Next, the CIGS complex solution according to a second mode of the present embodiment will be described.

In the present embodiment, the CIGS complex solution is prepared from the hydrazine-coordinated Cu chalcogenide complex component, the hydrazine-coordinated In chalcogenide complex component and the hydrazine-coordinated Ga chalcogenide complex component described above in the first mode, together with a hydrazine-coordinated Sb chalcogenide complex component.

A hydrazine-coordinated Sb chalcogenide complex component can be obtained by adding Sb selenide (Sb₂Se₃) and a chalcogen to hydrazine to obtain a crude product (a third crude product), extracting the crude product with DMSO, and adding a poor solvent to the resulting solution to perform recrystallization.

More specifically, Sb selenide and a chalcogen are added to hydrazine, and stirred at room temperature for about 3 to 7 days. Then, hydrazine is removed from the resulting solution while flowing nitrogen to obtain a crude product. Thereafter, the obtained crude product is extracted with DMSO.

Subsequently, the extraction solution obtained by extracting the crude product is subjected to filtration using, for example, a 0.2 μm PTFE filter. Then, a poor solvent is added to the filtrate for reprecipitation, thereby obtaining a black hydrazine-coordinated Sb chalcogenide complex.

The generation of the hydrazine-coordinated Sb chalcogenide complex described above can be expressed by a chemical formula (6) shown below.

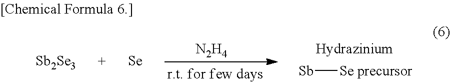

As the chalcogen, Se or S can be used, and Se is preferable. Further, as the poor solvent, the same poor solvents as those described above for the hydrazine-coordinated Cu chalcogenide complex component can be mentioned, and methanol, ethanol and isopropanol (IPA) are preferable. As hydrazine, anhydrous hydrazine or a water-containing hydrazine may be used, although hydrazine monohydrate is preferable. With respect to the amount of Sb selenide (Sb₂Se₃) and the chalcogen, it is preferable to use 2 mol or more of the chalcogen, per 1 mol of Sb selenide.

Although the present embodiment is described using Sb selenide, an elemental antimony may also be used instead of Sb selenide. In such a case, with respect to the amount of antimony (Sb) and the chalcogen, it is preferable to use 4 mol or more of the chalcogen, per 1 mol of antimony.

Next, the method of producing the CIGS complex solution according to the present embodiment will be described.

Firstly, DMSO is added to the hydrazine-coordinated Cu chalcogenide complex component described in the first embodiment and stirred at room temperature for about one night, thereby obtaining a DMSO solution having the hydrazine-coordinated Cu chalcogenide complex component dissolved therein (solution (I′)).

Further, DMSO is added to the hydrazine-coordinated In chalcogenide complex component and the hydrazine-coordinated Ga chalcogenide complex component described in the first embodiment, and stirred at a temperature of 80 to 120° C. for about 1 hour, thereby obtaining a DMSO solution having the hydrazine-coordinated In chalcogenide complex component and the hydrazine-coordinated Ga chalcogenide complex component dissolved therein (solution (II′)).

Furthermore, DMSO is added to the aforementioned hydrazine-coordinated Sb chalcogenide complex component, and stirred at room temperature for one night, thereby obtaining a DMSO solution having the hydrazine-coordinated Sb chalcogenide complex component dissolved therein.

In addition, 2 equimolar amounts of Se is added to Na₂Se, and stirred in DMSO at room temperature for 3 to 7 days, thereby obtaining a uniform solution.

In the present embodiment, Na is used for improving the film quality of the light-absorbing layer (e.g., grain size and crystalline quality), and this Na solution may not be used.

Subsequently, the aforementioned 4 solutions, Namely, the DMSO solution having the hydrazine-coordinated Cu chalcogenide complex component dissolved therein, the DMSO solution having the hydrazine-coordinated In chalcogenide complex component and the hydrazine-coordinated Ga chalcogenide complex component dissolved therein, the DMSO solution having the hydrazine-coordinated Sb chalcogenide complex component dissolved therein and the Na solution are mixed together.

In the manner as described above, a CIGS complex solution according to the present embodiment can be produced.

Like in the first embodiment, the CIGS complex solution according to the present embodiment is not deteriorated with time, and exhibits excellent storage stability.

Further, since the coating solution itself does not contain hydrazine, the chemical properties (explosiveness) of hydrazine in the formation of a light-absorbing layer would not be of any problems, thereby improving the safety of the production process.

[Production Method of a Solar Cell]

Next, the method of producing the coating solution for forming a light-absorbing layer according to the present invention will be described.

The method of producing a solar cell according to the present embodiment mainly includes the steps of forming a first electrode on a substrate, forming a light-absorbing layer on the first electrode, forming a buffer layer on the light-absorbing layer, and forming a second electrode on the buffer layer.

In the method, the steps other than the step of forming a light-absorbing layer on the first electrode can be performed by any conventional method. For example, the step of forming a first electrode on a substrate can be performed by a sputtering method using nitrogen as a sputtering gas, and forming a film layer such as an Mo layer. The buffer layer can be formed as a CdS layer by, for example, a chemical bath deposition method. The second electrode can be formed as a transparent electrode using an appropriate material.

In the formation of a light-absorbing layer, firstly, the aforementioned coating solution for forming a light-absorbing layer is applied to the first electrode (support). The application of the coating solution can be conducted by a spin-coat method, a dip-coat method, a doctor-blade (applicator) method, a curtain-slit cast method, a printing method, a spraying method or the like.

The application conditions can be appropriately selected depending on the desired film thickness, concentration of the materials and the like.

For example, in a spin-coating method, the support is set on a spin coater, followed by applying the coating solution to the support. The application conditions can be appropriately selected depending on the film thickness. For example, the application can be performed at a rotation speed of 300 to 3,000 rpm for 10 to 60 seconds.

In a dipping method, the support can be dipped in a container containing the coating solution. The dipping can be performed once, or a plurality of times.

After applying the coating solution for forming a light-absorbing layer on the support, a vacuum drying may be performed.

Subsequently, after applying the coating solution on the support, the support is baked to form a light-absorbing layer.

The baking conditions can be appropriately selected depending on the desired film thickness, the type of materials used, and the like. For example, the baking can be performed in 2 steps, namely, performing a soft bake on a hot plate (prebake), followed by baking in an oven (annealing).

In such a case, for example, the support may be set and held on a hot plate, followed by raising the temperature of the hot plate to 100 to 500° C. to perform the soft bake for 1 to 30 seconds. Then, the inside of the oven can be heated to 300 to 700° C., and maintained for 1 to 180 minutes to perform the annealing.

As a result, the light-absorbing layer is cured.

The baking temperatures described above are merely one example of the baking conditions, and the baking conditions are not particularly limited. For example, the temperature of the hot plate can be raised in a stepwise manner, and the heating may be performed in an inert gas atmosphere in a glove box.

Thereafter, the film thickness of the light-absorbing layer is measured. When the film thickness is smaller than the desired thickness, the coating solution for forming a light-absorbing layer is applied to the support again and baked. By repeating these steps, a light-absorbing layer having the desired thickness can be obtained.

The coating solution for forming a light-absorbing layer according to the present invention exhibits improved affinity for the back electrode, remedy occurrence of agglomeration of the coating solution after coating and before baking, and is capable of forming a uniform light-absorbing layer.

The reasons why these effects can be achieved has not been elucidated yet, but are presumed as follows. For forming a light-absorbing layer which exhibits satisfactory solar cell properties, it is desirable to use a homogeneous metal complex coating solution. For preparing a homogeneous metal complex coating solution, it is required to use a solvent in which metal(s) exhibit a high solubility. In general, a solvent in which metal(s) exhibit a high solubility has a high surface tension. By using such a solvent, a homogeneous metal complex coating solution can be prepared. However, due to the high surface tension of the solvent, when the coating solution is applied to a back electrode, the coating film formed is agglomerated toward the center of the film. As a result, by baking after the formation of the film, microcracks are formed on the film, such that satisfactory solar cell properties cannot be obtained.

In the present invention, after the preparation of a homogeneous metal complex coating solution by using a solvent in which metal(s) exhibit a high solubility (i.e., solvent exhibiting a high surface tension), by adding a specific amount of an alcohol having 1 to 5 carbon atoms which is a poor solvent for a metal, the surface tension of the coating solution can be lowered without causing precipitation of metals and the like (i.e., while maintaining the homogeneity of the metal complex solution). As a result, a homogeneous coating film can be formed. Further, since microcracks are not generated by baking after the formation of the film, it is expected that satisfactory solar cell properties can be obtained.

### EXAMPLES

As follows is a description of examples of the present invention, although the scope of the present invention is by no way limited by these examples.

### Example 1

### Production of Hydrazine-Coordinated Cu Precursor Solution

A metal Cu (383.0 mg, 6.03 mmol) and 4 equivalents of Se (1903.2 mg, 24.10 mmol) were stirred in DMSO (10 ml) at room temperature for 3 days in the presence of 2 equivalents of hydrazine relative to the Cu metal (378 μl, 12.05 mmol). Then, the remaining hydrazine was removed by flowing nitrogen, followed by concentration. Thereafter, the obtained concentrated solution was subjected to filtration using a 0.2 μm PTFE filter, thereby obtaining a hydrazine-coordinated Cu—Se complex/DMSO solution (concentration in terms of Cu: 1.124 mol/1) (hereafter, referred to as “solution (a)”).

(Production of Hydrazine-Coordinated Sn Precursor Solution)

A metal Sn (356 mg, 3.00 mmol) and 3 equivalents of Se (711 mg, 9.00 mmol) were stirred in hydrazine (5 ml) at room temperature for 3 days. Then, the remaining hydrazine was removed by flowing nitrogen, thereby obtaining a crude product. The crude product was extracted with DMSO (80° C., 1 hr), followed by filtering the extract using a 0.2 μm PTFE filter. Subsequently, IPA was added and stirred, thereby precipitating a dark-red product. Then, supernatant was removed, and the precipitate was washed with IPA and dried, thereby obtaining a dark-yellow hydrazine-coordinated Sn—Se complex (concentration in terms of Sn: 0.418 mol/1) (hereafter, referred to as “solution (b)”).

(Production of Hydrazine-Coordinated Zn Precursor Solution)

Zinc selenide (ZnSe, 460 mg, 4.02 mmol) and 5 equivalents of Se (1,588 mg, 20.11 mmol) were stirred in DMSO (8 ml) at room temperature for 1 week in the presence of 3 equivalents of hydrazine relative to ZnSe (12.07 mmol). Then, the remaining hydrazine was removed by flowing nitrogen, thereby obtaining a reaction intermediate solution. Subsequently, the reaction intermediate solution was extracted with DMSO at room temperature or under heated conditions (heated condition: 80° C., 1 hr). Then, the extracted liquid was subjected to filtration using a 0.2 μm PTFE filter, followed by concentration under reduced pressure. The obtained concentrated solution was filtered, thereby obtaining a hydrazine-coordinated Zn precursor solution (concentration in terms of Zn: 0.065 mol/1) (hereafter, referred to as “solution (c)”).

(Preparation of Na Additive Solution)

2 equivalents of Se (322.8 mg, 4.09 mmol) was added to sodium selenide (Na₂Se, 255.4 mg, 2.04 mmol), and stirred in DMSO (10 ml) at room temperature for 1 week, thereby obtaining a homogeneous black solution (concentration in terms of Na: 0.500 mol/1) (hereafter, referred to as “solution (d)”).

(Production of Coating Solution for Forming CZTS Layer)

The solution (a) (2.132 ml), the solution (b) (3.184 ml) and the solution (c) (25.000 ml) were mixed together, and then, the resulting solution was distilled to concentrate the solution to a desired concentration, followed by addition of the solution (d) (0.054 ml), thereby preparing a CZTS/DMSO precursor solution.

To the obtained CZTS/DMSO precursor solution was added ethanol in an amount of 0.1 vol %, thereby obtaining a coating solution for forming a CZTS layer.

### Example 2

A coating solution for forming a CZTS layer was prepared in the same manner as in Example 1, except that methanol was used instead of ethanol. As a result, a homogeneous coating solution for forming a CZTS layer was obtained.

### Example 3

A coating solution for forming a CZTS layer was prepared in the same manner as in Example 1, except that isopropanol was used instead of ethanol. As a result, a homogeneous coating solution for forming a CZTS layer was obtained.

### Comparative Example 1

A coating solution for forming a CZTS layer was prepared in the same manner as in Example 1, except that ethanol was not added.

### Comparative Example 2

A coating solution for forming a CZTS layer was prepared in the same manner as in Example 1, except that ethanol was added in an amount of 51 vol %. As a result, precipitation occurred, and a homogeneous coating solution for forming a CZTS layer could not be obtained.

### Examples 4 to 6

A coating solution for forming a CZTS layer was prepared in the same manner as in Example 1, except that the amount of ethanol added was changed from 0.1 vol % to 5 vol % (Example 4), 10 vol % (Example 5) or 20 vol % (Example 6). As a result, a homogeneous coating solution for forming a CZTS layer was obtained.

[Evaluation of Coating on Back Electrode]

Each of the coating solution for forming a CZTS layer obtained in Example 1 to 6 and Comparative Examples 1 and 2 was applied to a soda lime glass provided with Mo (Mo layer thickness: 800 nm) by a doctor blade method. Thereafter, soft bake was performed under baking conditions of 250° C./5 min on the coated side of the substrate, and 500° C./5 min on the opposite side of the coated side of the substrate, followed by annealing at 580° C. for 10 minutes.

As a result, when the coating solutions for forming a CZTS layer obtained in Examples 1 to 6 and Comparative Examples 1 were used, a CZTS layer was formed on the substrate. On the other hand, when the coating solution for forming a CZTS layer obtained in Comparative Example 2 was used, the coating solution could not be applied to the substrate.

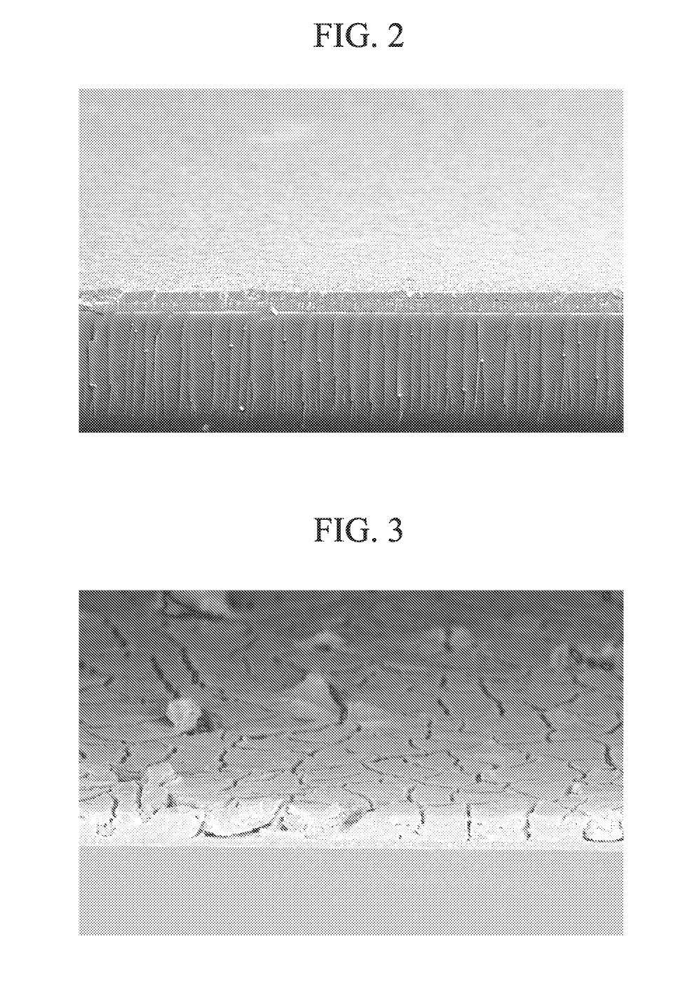

FIG. 2 is a photograph of the CZTS layer formed using the coating solution produced in Example 1, as measured by a scanning electron microscope (SEM). FIG. 3 is a photograph of the CZTS layer formed using the coating solution produced in Comparative Example 1, as measured by a scanning electron microscope (SEM).

As shown in FIG. 2, it was confirmed that the CZTS layer formed using the coating solution prepared in Example 1 had no generation of cracks, and was a homogeneous film.

On the other hand, as shown in FIG. 3, it was confirmed that the CZTS layer formed using the coating solution prepared in Comparative Example 1 suffered generation of microcracks after the soft bake, and the crack further grew by the high temperature annealing, thereby exhibiting large cleavages.

From the results shown above, it was confirmed that the coating solution for forming a CZTS layer according to the present invention having an alcohol of 1 to 5 carbon atoms added after preparation of the metal complex solution was capable of suppressing generation of microcracks, and a homogeneous coating film can be formed.

With respect to the CZTS layers formed using the coating solutions prepared in Examples 2 to 6, generation of cracks could be suppressed, and homogeneous films could be obtained, as compared to the CZTS layer formed using the coating solution prepared in Comparative Example 1.

While preferred embodiments of the invention have been described and illustrated above, it should be understood that these are exemplary of the invention and are not to be considered as limiting. Additions, omissions, substitutions, and other modifications can be made without departing from the spirit or scope of the present invention. Accordingly, the invention is not to be considered as being limited by the foregoing description, and is only limited by the scope of the appended claims.

What is claimed is:

1. A coating solution for forming a light-absorbing layer of a solar cell obtainable by dissolving at least one metal or metal compound selected from the group consisting of a group 11 metal, a group 12 metal, a group 13 metal, a group 14 metal, a group 11 metal compound, a group 12 metal compound, a group 13 metal compound and a group 14 metal compound in a solvent to obtain a metal complex solution, and adding 0.1 to 50 volume % of an alcohol having 1 to 5 carbon atoms to the metal complex solution.

2. The coating solution according to claim 1, wherein 1 to 40 volume % of an alcohol having 1 to 5 carbon atoms is added to the metal complex solution.

3. The coating solution according to claim 1, wherein 5 to 30 volume % of an alcohol having 1 to 5 carbon atoms is added to the metal complex solution.

4. The coating solution according to claim 1, wherein the at least one metal or metal compound is selected from the group consisting of Cu element, Zn element, Ga element, In element, Ge element, Sn element, Cu metal, Cu(OH)₂, Cu₂S, Cu₂Se, CuO, Cu₂O, silver oxide, silver sulfide, Zn metal, ZnSe, ZnO, zinc hydroxide, In₂Se₃, indium oxide, indium sulfide, gallium oxide, Sn metal, SnS, SnSe, SnSe₂, SnO and germanium oxide.

5. A method of forming a coating solution for forming a light-absorbing layer of a solar cell, the method comprising:
a step of dissolving at least one metal or metal compound selected from the group consisting of a group 11 metal, a group 12 metal, a group 13 metal, a group 14 metal, a group 11 metal compound, a group 12 metal compound, a group 13 metal compound and a group 14 metal compound in a solvent to obtain a metal complex solution; and
a step of adding 0.1 to 50 volume % of an alcohol having 1 to 5 carbon atoms to the metal complex solution.

6. The method according to claim 5, wherein 0.1 to 40 volume % of an alcohol having 1 to 5 carbon atoms is added to the metal complex solution.

7. The method according to claim 5, wherein 0.1 to 30 volume % of an alcohol having 1 to 5 carbon atoms is added to the metal complex solution.

8. The method according to claim 5, wherein the at least one metal or metal compound is selected from the group consisting of Cu element, Zn element, Ga element, In element, Ge element, Sn element, Cu metal, Cu(OH)₂, Cu₂S, Cu₂Se, CuO, Cu₂O, silver oxide, silver sulfide, Zn metal, ZnSe, ZnO, zinc hydroxide, In₂Se₃, indium oxide, indium sulfide, gallium oxide, Sn metal, SnS, SnSe, SnSe₂, SnO and germanium oxide.
